(19) United States
(12) Patent Application Publication
(10) Pub. No.: US 2003/0232174 A1
(43) Pub. Date: Dec. 18, 2003

(54) Method of making a flexible substrate containing self-assembling microstructures

(75) Inventors: Pi Chang, Arcadia, CA (US); Philip Yi Zhi Chu, Monrovia, CA (US); Dong Hseih, Arcadia, CA (US); Robert M. Pricone, Libertyville, IL (US); W. Scott Thielman, Palatine, IL (US)

Correspondence Address: RENNER, OTTO, BOISSELLE & SKLAR, LLP, 1621 EUCLID AVENUE, NINETEENTH FLOOR, CLEVELAND, OH, 44115-2191, US

(73) Assignee: Avery Dennison Corporation, Pasadena, CA (US)

(21) Appl. No.: 10/417,782

(22) Filed: Apr. 17, 2003

Related U.S. Application Data
(63) Continuation of application No. 09/776,281, filed on Feb. 2, 2001.

(51) Int. Cl. B32B 3/00

(52) U.S. Cl. 428/156; 264/400; 264/494; 264/285

(57) ABSTRACT

A substrate having embossed thereon a plurality of shaped recesses of a predetermined precise geometric profile, each recess having a flat bottom surface having a major dimension of about 500 μm or less, the substrate being capable of undergoing a thermal cycle of about one hour at about 150° C. while maintaining about ±10 μm or less dimensional stability of the embossed shaped indentations, and wherein the substrate comprises an amorphous thermoplastic material. During the thermal cycle the substrate has an elastic modulus greater than about 10¹⁰ dynes/cm² and a viscoelastic index of less than about 0.1.

### CROSS-REFERENCE

This application is a continuation of U.S. Ser. No. 09/776,281, filed Feb. 2, 2001, which was related to provisional application Serial No. 60/252247, currently pending (Attorney Docket no. AVERP2951DUS), filed Nov. 21, 2000, entitled Display Device and Method of Manufacture and Control.

### BACKGROUND OF THE INVENTION

The present invention relates to the field of electronic integrated circuits, and particularly to the disposition of microstructure circuit elements on a flexible substrate.

The invention relates primarily to the manner of selecting and forming a flexible substrate surface on which may be embedded microelectronic components, and to the formed substrate. There has been a need, particularly in the field of flat panel displays, smart cards and elsewhere, for microelectronic devices or chips that can be integrated into or assembled as either a system or a larger array, in a relatively inexpensive manner.

Liquid crystal display (LCD) devices are well known and are useful in a number of applications in which light weight, low power requirements and a flat panel display are desired. Typically, these devices comprise a pair of sheet-like, glass substrate elements or “half-cells” overlying one another with liquid crystal material confined between the glass substrates. The substrates are sealed at their periphery with a sealant to form the cell or device. Transparent electrodes are generally applied to the interior surface of the substrates to allow the application of an electric field at various points on the substrates thereby forming addressable pixel areas on the display.

Various types of liquid crystal materials are known in the art and are useful in devices referred to as twisted nematic (TN), super twisted nematic (STN), cholesteric, and ferroelectric display devices.

In the manufacture of laptop computer screens, a thin film of integrated circuits may be deposited on glass to control the light emitting elements. But because glass is fragile, building large displays is extremely difficult and expensive. Alternatively, trying to put microelectronics directly on plastic requires such high heat that the plastic passes its glass transition temperature and melts. The improved microreplicated substrates and materials therefor of the present invention are useful in a variety of such LCD devices. For example, the ability to withstand elevated processing temperatures can be useful during the sealing of LCD devices. The ability to maintain dimensional stability in a micro-embossed substrate can be useful in high-resolution displays, wherein dimensional tolerances are critical.

In recent years, the company known as Alien Technology Corporation, in Morgan Hills, Calif., has developed significant techniques for manufacturing microelectronic elements or “NanoBlocks,” and then depositing these elements on an underlying substrate at precisely determined locations, using a technique known as fluidic self assembly, or FSA. In particular, that Alien Technology method includes forming the “NanoBlocks”, forming a substrate with recesses complementary in shape to the microstructure blocks, and then transferring the shaped microstructure blocks or structures via a fluid or slurry onto the top surface of the substrate having the recessed regions or binding sites or receptors. Upon transference, the blocks self-align through their shape into the recess regions and integrate thereon.

The compositions and the various processing techniques used to produce the microstructure blocks, the underlying substrates, and additional processing operations after the blocks are disposed on the substrate, are disclosed in a number of patents owned by or licensed to Alien Technology, including the following, the disclosures of which are incorporated in full herein by reference: U.S. Pat. Nos. 5,783,856; 5,824,186; 5,904,545; and 5,545,291. Additional information relating to this subject matter also is found in Alien Technology PCT publications, also incorporated in full by reference: WO 00/49421; WO 00/49658; WO 00/55915; and WO 00/55916. A recent publication about the Alien processing technique is found in the Society for Information Display (SID), November 2000, Vol. 16, No. 11 at pp. 12-17.

The resulting structure that is created using the described techniques may include a variety of useful electronic circuits that contain silicon-based electronic devices and may be fabricated into things such as LCDs, lasers, tunneling transistors, integrated circuits, solar collectors and others. It may be used in any device that needs some layer of integrated chips, including devices known as “smart cards.”

Smart cards are devices about the size of a conventional credit card and having an embedded electronic microchip. The chip stores electronic data and programs protected by a security feature. There are two types of smart cards: contact and contactless. Contact smart cards have a small gold plate about ½″ in diameter on the front, instead of a magnetic strip on the back like a credit card. When inserted in a reader, contact between the gold plate and electrical connectors transfers data to and from the chip. Contactless smart cards are passed near an antenna to carry out a transaction. Again, the card looks like a plastic credit card except that it has an electronic microchip and an antenna embedded inside. These components allow the card to communicate with an antenna/transceiver unit without physical contact. Typically, the size of the card is determined by certain international standards (ISO 7810; 7816). The ISO 7816 standard also defines physical characteristics of the plastic of the card, including the operable temperature range and flexibility, position of electrical contacts, and how the microchip is to communicate with the outside world. One major manufacturer of smart cards is Gemplus SA. Information about them can be obtained at www.gemplus.com.

Alien Technology has been working with applicants' assignee to identify materials and develop processing techniques for efficiently producing rolls of a flexible substrate that could be used in the manufacture of smart cards that would meet product specifications. It is desirable that the substrate surface carrying the microstructure blocks be flexible, thereby increasing the variety of products with which the assembly may be employed—both from the standpoint of shape and durability. Moreover, manufacturing efficiency suggests that use of a continuously formed substrate would have advantages over substrates produced in batches.

The method of identifying a satisfactory flexible substrate material is one object of the present invention. In the first instance, the substrate material must be capable of being formed with highly accurate and very small recesses. The flatness of the recess bottom surface is particularly important in allowing the block to self align in proper position on the substrate. One technique of microreplicating arrays with very small surfaces requiring a high degree of flatness and accuracy, is found in the use of continuous embossing to form cube corner sheeting, as used by applicants' assignee. A detailed description of equipment and processes to provide optical quality sheeting is disclosed in U.S. Pat. Nos. 4,486,363 and 4,601,861. Tools and a method of making tools used in those techniques are disclosed in U.S. Pat. Nos. 4,478,769; 4,460,449; and 5,156,863. The disclosures of all such patents are incorporated herein by reference; all are assigned to applicants' assignee.

While it is believed that prior Alien Technology materials, as suggested for example in PCT/US99/30391 (WO 00/46854) at p. 8, for the display tape (and not the flexible substrate), conceivably could be successfully embossed on a continuous basis, based on applicants' tests of some of such materials (polypropylene and polymethyl methacrylate), it is believed that these materials would not meet stringent dimensional stability requirements.

Preferably, the microstructure receptor recesses will be formed in a manner that will not introduce latent stresses in a flexible substrate. Preferably, the substrate also will satisfy the following criteria: (a) dimensional stability after formation, at a number of processing temperatures; (b) resistance to certain chemicals required during FSA and subsequent photoresist processes; (c) adhesion to certain chemicals; and (d) flatness.

More specifically, the preferred embossed flexible substrate will be dimensionally stable at 150° C. for one hour; will be microreplicable at high temperatures (even as high as 400° C.); will exhibit good adhesion with an overlying planarizing layer; will exhibit good chemical resistance in subsequent processing steps; and will meet certain lay flatness requirements.

The preferred embossed substrate material will be dimensionally stable in at least two respects: locally (the dimensional accuracy of each embossed recess) with accuracy of ±10 μm or less (x,y) and ±5 μm or less (z); and globally (the distance between one or more recesses in an area of 6″×6″ (15.24 cm×15.24 cm) from predetermined reference points) with accuracy of ±20 μm or less. Preferably, this stability should remain throughout all processing steps, particularly after heating and aging. The preferred substrate will be able to withstand a planarization process, wherein it is effectively baked at about 150° C. for about one hour.

The preferred substrate also will be resistant to various chemicals, including the FSA solution (water, a surfactant and a bonding agent); solvents, including PGMEA (propylene glycol monomethyl ether acetate); other photoresist developers and etching compounds; solder mask solvent; solder mask developers; solder mask rinses; photoresist developers; aluminum etching; and photoresist strippers. More detailed specifications of chemical resistance are listed hereinafter.

In developing methods for identifying materials that are both embossable for precise configuration of the receptor recesses and processable at the various processing temperatures, while still meeting the stability and chemical resistance requirements for both processing and the finished product, applicants have conceived a Theological window to define a range of parameters (E′, the elastic modulus; tan delta, the viscoelastic index) using ASTM measurements for the selection of the film substrate. Based upon the use of this Theological window, and based upon testing of a number of potential materials, successful substrate materials have been identified, and after FSA and planarization, these materials should provide a new subassembly combination capable of further processing.

For purposes of the present invention, three temperature reference points are used: T_{g}; Tₑ; Tₚ.

T_{g} is defined as the glass transition temperature, at which plastic material will change from the glassy state to the rubbery state. It may comprise a range before the material may actually flow.

Tₑ is defined as the embossing or flow temperature where the material flows enough to be permanently deformed by embossing equipment, and will, upon cooling, retain the embossed shape. Because Tₑ may vary from material to material and can depend on the thickness of material and the nature of the dynamics of the embossing equipment, the exact temperature may not be known but is related to the temperature input of the equipment and its speed.

Tₚ, for purposes of this patent, is the highest processing temperature to which the embossed substrate material will be exposed in any post embossing processing steps, and will always be somewhat less than T_{g} for the specific material.

It is a primary object of the invention to provide a substrate capable of having embossed thereon a plurality of shaped recesses of a predetermined precise geometric profile, each recess having a flat bottom surface, the substrate so embossed being capable of undergoing a thermal cycle of about one hour at about 150° C. while maintaining about ±10 μm or less dimensional stability of the embossed shaped indentations, and wherein the substrate comprises an amorphous thermoplastic material. Preferably the recess will have a tapered wall, being larger at the top of the recess than at the bottom.

It is a further object of the invention to assure that during the subsequent processing cycle, Tₚ, the substrate has an elastic modulus greater than about 10¹⁰ dynes/cm², and a viscoelastic index of less than about 0.1.

Yet another object of the invention is to provide a substrate that is substantially chemically inert to an aqueous solution of 5% non-ionic surfactant for about one hour of exposure at about 30° C. during the FSA process; and subsequently to a solution of about 60% propylene glycol monomethyl ether acetate for about 30 minutes of exposure at about 90° C., during planarization and via formation.

Still another object is to provide a substrate that also is substantially chemically inert to a solution of about 72% phosphoric acid, about 14% acetic acid, and about 3% nitric acid for about 2 minutes of exposure at about 50° C.; and to a solution of about 10% monoethanolamine for about one minute of exposure at about 50° C.

Yet another object is to provide the substrate wherein the material comprising the amorphous thermoplastic is in the form of a flexible web capable of being wound about a core.

Still another object is to provide a substrate of the character described and having sufficient dimensional stability so that the thermal cycle does not affect the global spacing by more than about ±20 μm or less.

Another object of the invention is to provide a substrate wherein the amorphous thermoplastic material is selected from the group consisting of polyarylate, polysulfone, polyetherimide, cyclo-olefinic copolymer, and high T_{g} polycarbonate.

Still another object is to provide such a substrate comprising a multi-layer structure.

A further primary objective of the invention is to provide an article comprising a substrate comprising a first amorphous thermoplastic layer having embossed on a first surface thereof a plurality of recesses of a precise geometric profile, each recess having a flat bottom surface having a length and width of about 500 μm or less; a plurality of microstructures each respectively disposed within one of the recesses, the microstructures having a geometric profile complementary to the geometric profile of the recesses; and a dielectric planarization layer disposed over the microstructures and the first surface of the amorphous thermoplastic substrate.

Another object is to provide a substrate of the character described, wherein each recess is formed with a flat bottom surface in the range of about 10 to 1000 μm in length and width; includes walls at an angle to the bottom surface in the range of 50°-70°; a depth in the range of about 5 to 1000 μm; and a top opening in the range of about 10 to 2000 μm in length and width, with the preferred dimension of 500 μm or less.

Another object is to provide, in the substrate so described a second amorphous thermoplastic layer disposed opposite the first surface of the amorphous thermoplastic layer in laminar configuration therewith, the second amorphous thermoplastic layer having a dimensional stability of <0.01% change in dimension, an elastic modulus of greater than about 10¹⁰ dynes/cm², and a viscoelastic index of less than about 0.1, all at a temperature of about 150° C. for about 1 hour.

Still another object of the invention is to provide a substrate comprising at least two layers in laminar configuration, the first layer of the substrate having recesses embossed thereon and a second layer having a dimensional stability of <0.01% change in dimension, an elastic modulus of greater than about 10¹⁰ dynes/cm², and a viscoelastic index of less than about 0. 1, all at a temperature of about 150° C. for about 1 hour.

A second major object of the invention is to provide a method of assembling a microstructure on a substrate, the substrate comprising a top surface with at least one precisely embossed recessed region thereon, the method comprising the steps of: 1) providing a slurry comprising a plurality of shaped micro blocks and a fluid; 2) transferring the slurry over the substrate at a rate at which at least one of the shaped micro blocks will self align and be disposed into a recessed region; and 3) subjecting the substrate with the shaped micro blocks disposed therein to elevated temperatures for subsequent processing, and wherein the substrate employed in the method comprises a first layer of an amorphous polymeric material, the material having an embossing temperature Tₑ at which Tₑ the elastic modulus of the substrate is less than about 1×10⁸ dynes/cm², and preferably 1×10⁶, and the viscoelastic index of the substrate is greater than about 0.3, the substrate being capable of subsequent processing at a processing temperature Tₚ, such that after about one hour at Tₚ the substrate has a dimensional stability of <0.01% change in dimension, an elastic modulus of greater than about 10¹⁰ dynes/cm², and a viscoelastic index of less than about 0.1.

Yet another object of the invention is to provide a method for forming an amorphous thermoplastic product having precise embossed micro recesses, comprising the steps of: providing a continuous press having a pair of opposed belts, at least one of the belts having a predetermined pattern; passing a web of amorphous thermoplastic material between the opposed belts; heating the material above T_{g} the glass transition temperature of the amorphous thermoplastic material to Tₑ; applying pressure to the amorphous thermoplastic material through the belts sufficient to emboss the predetermined pattern of precise micro recesses on a surface thereof; and cooling the amorphous thermoplastic material to below its glass transition temperature.

It is yet a further object of the invention to provide a substrate material for a process wherein the temperature of T_{g} is greater than about 150° C. and less than about 400° C., and Tₚ is less than or equal to about 150° C.

Still another object of the invention is to provide such a flexible substrate wherein the dimensional stability of the substrate after all processing is such that each recessed region therein will maintain a global distance that will not vary by more than ±20 μm or less.

A further object of the invention is to provide a substrate material wherein after being subjected to all processing steps, the dimensions of each recessed region shall not change by more than ±10 μm (x, y) and ±5 μm (z).

A further object of the invention is to provide a multilayer substrate, wherein one of the layers is capable of being embossed with recesses at Tₑ and at least a second layer maintains dimensional stability for the substrate at Tₚ.

Yet another object of the invention is to provide an extended length of flexible embossable substrate capable of being wound on a core, the substrate capable of being embossed with an array of micro recesses of precise shape, having flat bottom surfaces and tapered walls, the substrate comprising an amorphous polymeric material selected from the group consisting of polyarylate, polysulfone, polyetherimide, cyclo-olefinic copolymer, and high T_{g} polycarbonate.

To accomplish the foregoing and related objects, the present invention includes the features hereinafter fully described and particularly pointed out in the claims. The description and drawings set forth in detail certain illustrative embodiments of the invention, which embodiments are indicative only of various ways in which the principles of the invention may be employed. Other objects, advantages, and novel aspects of the invention will become apparent from the following detailed description of the invention when considered in conjunction with the drawings.

### BRIEF DESCRIPTION OF THE DRAWINGS

In the annexed drawings:

FIG. 1 is an illustration of examples of shaped microstructure blocks;

FIG. 2. is a schematic showing how trapezoidal shaped microstructure blocks tumble onto an underlying substrate during FSA;

FIG. 3 is representative of a roll process for FSA placement of blocks onto the underlying substrate;

FIG. 4 is a partial perspective view showing the receptor recesses as formed in an underlying flexible substrate in accordance with the present invention;

FIG. 5 is a perspective view of a tool for microreplication of a pattern on a substrate, with male members for forming the receptor recesses located thereon;

FIG. 6 has an upper portion illustrating FSA with random positioning of microstructure blocks on the underlying substrate, and a lower portion in which each of the blocks is positioned in a recess in the substrate;

FIG. 7 is a high level flow chart of a method for constructing one type of display device utilizing the substrate of the present invention;

FIG. 8 shows in greater detail in end and partial conceptual fashion, the process steps of FIG. 7 in forming one type of LCD display device;

FIG. 9 is a partial perspective view showing the wiring layer of one of the processing steps of FIGS. 7 and 8;

FIG. 10 is an enlarged exemplary view in partial cross section showing microstructure blocks on the underlying substrate and produced in accordance with the processing steps of FIGS. 7 and 8;

FIG. 11 is a high-level flow chart for a method for constructing a “smart card”;

FIG. 12 illustrates three different substrates which comprise part of the present invention;

FIG. 13 is a greatly enlarged cross sectional view illustrating the precise architecture of an embossed receptor recess and the representative dimensions of a trapezoidal block element intended to be positioned therein;

FIG. 14 is a diagrammatic end view of one type of embossing equipment which may be used to form the receptor recesses on the underlying substrate;

FIG. 15 illustrates in perspective schematic view another type of equipment for embossing the precise receptor recess pattern in the underlying substrate; and

FIGS. 16A-16E illustrate temperature dependence of rheological properties of different substrate materials.

### DETAILED DESCRIPTION OF THE INVENTION

There literally are thousands of thermoplastic materials available which may be considered as possible contenders for a substrate that could be formed to provide the necessary shaped receptor microstructure recesses. However, not all can be embossed on a continuous basis; nor can all meet the major general parameters discussed hereinabove or the specifications set forth hereinafter. In accordance with the instant invention, applicants herein have conceived a relationship of parameters defining a rheological window which, when coupled with other specifications, facilitates the identification of materials that will meet the general specifications set forth herein.

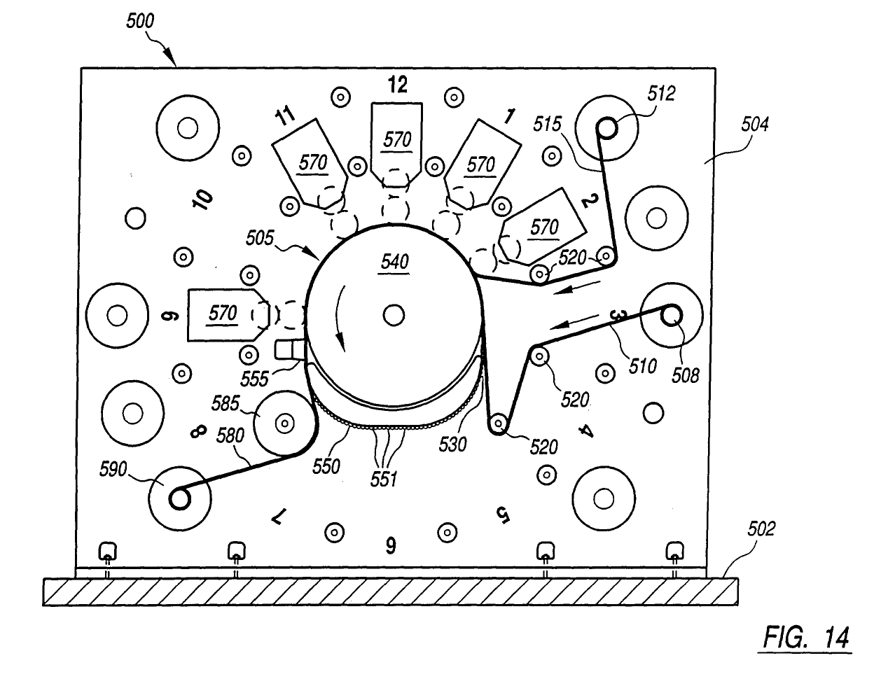

Embossing equipment of the type illustrated in FIG. 14 herein has been used for microreplication of cube corner sheeting and other structures, but typically the embosser runs at lower temperatures. The typical materials used to emboss cube corner sheeting (manufactured, for example using applicants' assignees existing equipment), and including polymethyl methyacralate, low T_{g} polycarbonate, and vinyl, are not capable of meeting the rheological window disclosed and claimed herein. The glass transition T_{g} temperatures for such materials are 100° C., 150° C. and 72° C., respectively, and clearly by themselves would not withstand Tₚ≦150° C. while maintaining dimensional stability.

Normally, embossing a polymer can result in frozen and built-in stresses which can cause dimensional instability. Similarly, shrinkage due to crystallization during some of the baking steps, with polymer relaxation during cooling, impacts the dimensional stability of the material. Thus, a determination that the substrate material must be amorphous is one aspect of the invention.

In accordance with the invention, it is preferred to identify two temperature points to define a Theological window in which the substrate will exhibit the desired dimensional stability. The first temperature point, defined herein as Tₑ, must be high enough to exceed the glass transition temperature T_{g}, so that flow of the material can be achieved, thereby allowing highly accurate embossing of the substrate.

The second temperature point, defined herein as Tₚ, is for those processes including a subsequent planarization baking step at about 150° C. (302° F.) for about 1 hour. Semicrystalline polymers are effectively ruled out for such processes, because such polymers may crystallize during that baking cycle and cause densification or shrinkage of the materials.

Certain preferred substrates include those that meet the following criteria (among others), some provided by Alien Technology Corporation, or in patents or publications and others being industry-recognized requirements for processes such as planarization and photo-resist technologies:

### General Material Specifications

It is desired that the substrate material, after embossing and processing, retain a recess shape of ±10 μm for sizes of up to 1000 μm and for certain uses. For roll to roll manufacture, the total thickness should be less than 200 μm. The accuracy of each receptor site or recess should be 10 μm or less, and the sheet should have a global accuracy of ±20 μm or less, depending upon the end use of the material, e.g. smart cards or LCD panels. The material must maintain this dimensional stability through a planarization process which typically occurs at about 150° C. for one hour. Significant dimensional stability also is required for levels of humidity variations of ±10RH and over a temperature variation of ±1° C.

The substrate must have significant chemical resistance to the FSA process, which includes exposure to DI water, non-ionic surfactants and bonding agents at about 30° C. for one hour.

The substrate material also must be inert to various industry recognized solvents, acids and bases used during planarization, masking and photoresist events. These exposures may run for periods from one minute to 30 minutes and at temperatures ranging from 30° to 100° C.

The term micro block or microstructure as used in this application is intended to generically refer to very small structures of the dimensional order noted herein, but some deviation from such dimensions may be acceptable depending upon the material's end use.

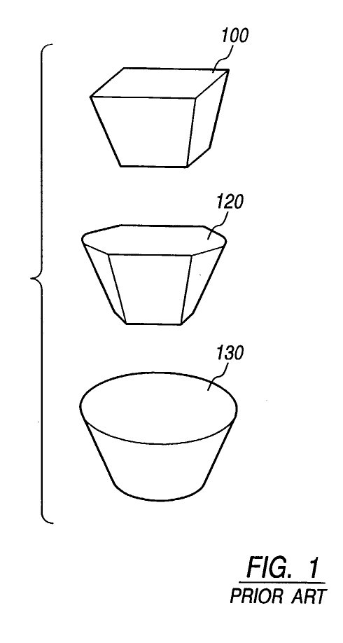

Examples of “NanoBlocks” containing microcircuitry and the method of their manufacture are found in the aforementioned Alien Technology patents. The blocks' circuit formation starts with generally standard silicon wafers fabricated by existing IC foundries. The process thereafter separates the wafers into millions of tiny block circuits. A standard backside wafer grind/polish technique is used, and a backside mask defines the chip. The chips are separated from the wafer, and the ultimate blocks (as illustrated herein in FIG. 1) consist of a microcircuit structure (not illustrated but understood to be on each block) with truncated pyramids having 54.7° beveled edges. Several shapes of the blocks are depicted generally in FIG. 1 at 100, 120, and 130. In one preferred embodiment, for a smart-card, the micro block has the shape and general dimensions indicated in FIG. 13, and the embossing tool would have dimensions generally complementary to the specific size of the nanoblock.

One preferred microstructure block shape comprises a truncated pyramid with a base and four sides. Each side creates an inwardly tapering angle of between about 50° and about 70° with respect to the base, with 54.7° being the preferred angle for the particular device. Each side may also have a height between about 5 μm and about 200 μm. The base also may have a length between about 10 μm and about 1000 μm and a width between about 10 μm and about 1000 μm.

As described in one of the earlier Alien Technology patents (5,904,545), the flatness of the bottoms of the recess regions is very important because nonuniformity could, during FSA, either prevent blocks from entering the recess regions or allow blocks to be drawn out of those regions. Moreover, if the recesses are too shallow, the blocks may fill improperly or a portion of the block may protrude above the surface and be drawn out. Similarly, if the recesses are too deep, the block may not settle all the way into the recess to receive proper support on the bottom.

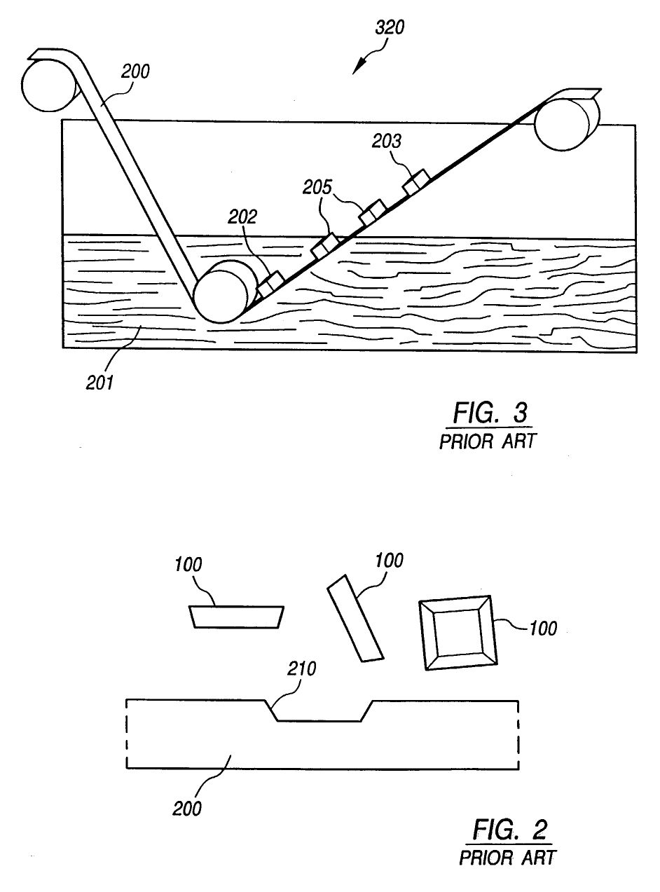

The applicants herein have found that the preferred substrate material 200 (FIG. 2), as detailed more fully hereinafter, is an amorphous flexible thermoplastic material having an array of precise receptor micro recesses 210 that are formed in the substrate by a continuous embossing process more fully described hereinafter. As noted, an important aspect of the present invention is the applicants' determination of the Theological window used to identify those particular materials that can be accurately embossed and that also can withstand the FSA process, such as that illustrated in FIGS. 2, 3, and 6, and the planarization process.

During the FSA process, a large number of the microstructure elements 100 are added to a fluid creating a slurry 201. The slurry is sprayed on or otherwise flows over the substrate material 200 with the receptor recesses 210. By chance some of the microstructure blocks 100 will fall into and, because of their shape, self align in the recesses 210. Once a microstructure block 100 flows into a recess 210, the microstructure element is retained in the close-fitting recess 210 by hydrodynamic forces. Further details regarding the manufacture of the microstructure blocks and the FSA processes may be found in U.S. Pat. Nos. 5,545,291 and 5,904,545; and PCT/US99/30391 as published at WO 00/46854, the entire disclosures of which are herein incorporated by reference.

After the FSA process, the substrate 200 may be checked for empty recess regions, for example by using an electronic eye attached to a machine capable of viewing the surface of the substrate material. Empty recess regions 210 may be filled, for example as suggested by Alien Technology, by using a robot to place a microstructure element 100 therein.

As illustrated in FIG. 3, in accordance with a preferred embodiment of the instant invention, the FSA process preferably is performed as a continuous roll operation by pulling the web of substrate material 200 through a bath of the slurry 201. Vacuum devices 202 and 203 may pull excess fluid and/or impurities off the substrate web 200 at the start and end of the FSA process. Spray devices 205 may be utilized to spray the slurry 201 onto the substrate web 200. The rate at which the slurry 201 is sprayed onto the substrate web 200 may be such that the number of microstructure blocks 100 falling past any given area of the substrate web, is several times the number of the receptor recesses 210 in that area of the substrate material 200. An excess number of the microstructure blocks 100 may be required in order to obtain full filling of all the receptor recesses 210. The slurry 201 generally may be reused, since the excess microstructure blocks 100 therein generally do not suffer damage by collision with the substrate material or with each other, due to hydrodynamic forces.

The FSA process may be used for filling receptor recesses of two different sizes with microstructure blocks of two or more different sizes or shapes, such as 120 or 130 as illustrated in FIG. 1, or others. During filling operations with two different sizes or shapes of recesses, larger (or otherwise shaped) blocks are unable to fit into smaller or differently shaped recesses 210. Additionally, hydrodynamic forces tend to cause smaller microstructure blocks to be pulled out of any larger recesses that the smaller blocks happen to enter. If blocks of different sizes are used, a slurry containing the blocks of one size may be sprayed on the substrate web 200 from one of the spray devices 205 and blocks of another size may be sprayed with another device. In each instance, however, the accuracy of the embossed recess is important to the FSA process.

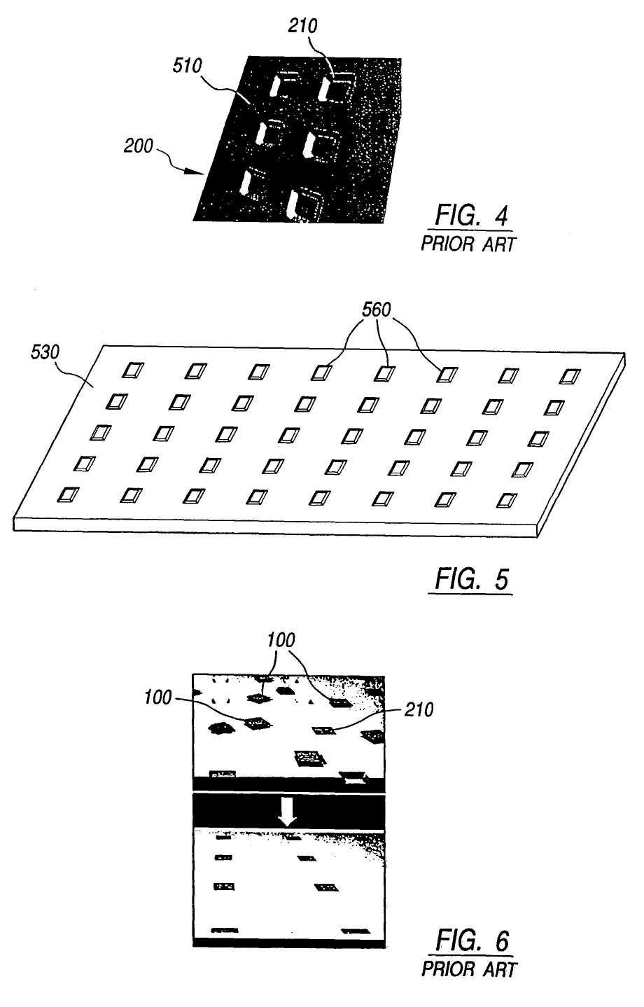

FIG. 4 illustrates, in perspective view, a portion of a web 510 that has been embossed using the embossing equipment described hereinafter to provide a substrate web 200 having an array of precisely formed recesses 210.

In the upper portion of FIG. 6, certain of the receptor recesses 210 are shown with microstructure blocks 100 therein and other blocks 100 lying loosely on the substrate upper surface in various positions. In the lower portion of FIG. 6, all of the microstructure blocks 100 are positioned in respective recesses 210.

FIG. 5 illustrates, in perspective, a portion of an embossing tool 530 used in the embossing equipment 500 of FIG. 14. The configured array 560 illustrates exemplary male members on the embossing tool 530. A tool such as this could be used to create the necessary receptor recesses 210 in a pattern such as that illustrated in the partial embossed substrate web 200 of FIG. 4, and having the general shape illustrated in FIG. 13.

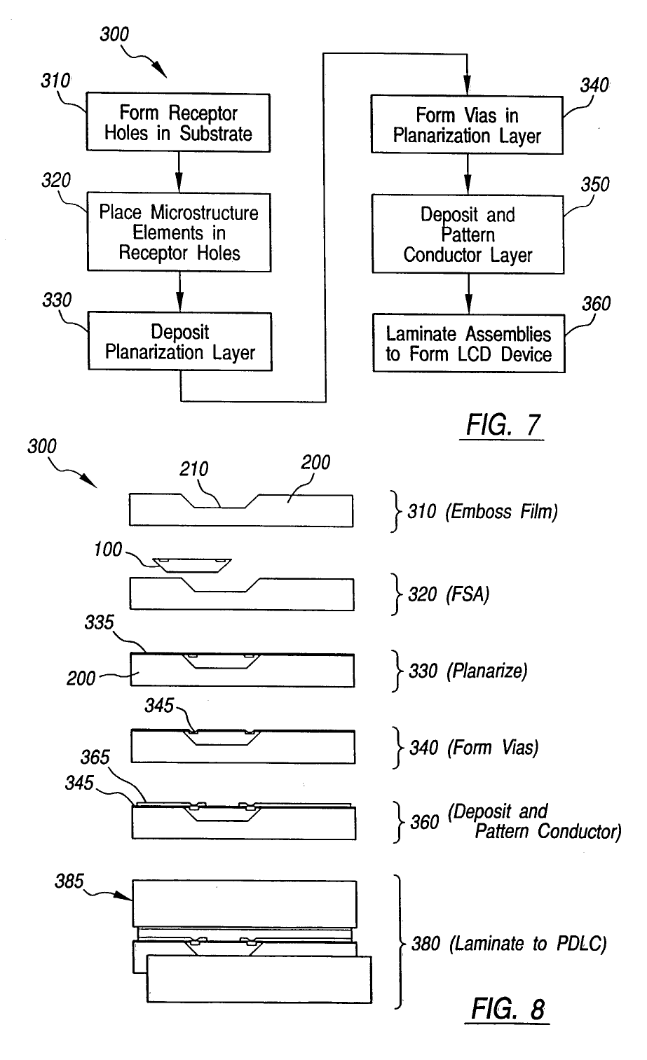

With reference now to FIG. 7, a flowchart describes steps for a method 300 of producing, at least in this instance, an LCD device such as that disclosed in co-pending provisional patent application (attorney docket AVERP-2951US) Ser. No. 60/252247, filed Nov. 21, 2000.

FIG. 7 is a high level flowchart showing the different steps utilizing the subject matter of the present invention. The preliminary step 310 requires embossing of the web of selected substrate material to form the receptor recesses 210. In step 320, the microstructure elements are disposed in the receptor recesses using the FSA technique.

In step 310 of the method 300, as illustrated in FIGS. 7 and 8, the substrate web 200 of the present invention has a plurality of suitable receptor recesses 210 formed therein. The recesses 210 preferably have a suitable shape or shapes for receiving the microstructure blocks, such as those in this instance shown as 100 in FIG. 1 and as described above.

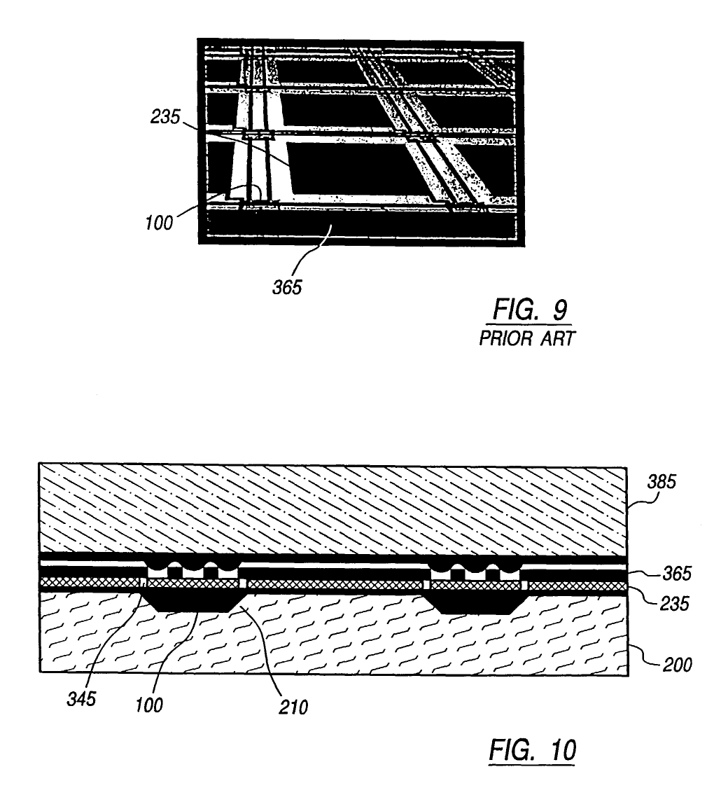

According to step 330, a planarization layer 335 (FIGS. 8, 10) of the type disclosed in the aforementioned Alien Technology patents is laid down over the microstructures which have been deposited in the array of receptor recesses. That planarization technique typically requires a curing step at about 150° C. for about one hour or longer. Thereafter, vias 345 (FIGS. 8, 10) are formed in the planarization layer to enable a connection to appropriate wiring which, pursuant to step 360, is laid down as a positive pattern of a conductive material (FIG. 9). Finally, the completed assembly may be laminated 380 to provide an appropriate device 385 (in this case generically disclosed as an LCD device). FIG. 9 illustrates a wiring pattern 365 which may be applied using a typical photoresist technique and FIG. 10 is an enlarged view of the same device as is generally illustrated in FIG. 8.

As described in the above-referenced Alien patents, the planarization technique includes laying down a uniform dielectric resin coat that will completely cover the substrate and the NanoBlock circuits. The purpose of the planarization is to fill any gaps that still may be present; to provide a smooth, flat surface for later processes, such as the etching of vias; to assure that the microelectronic elements are maintained in position in their recesses on the substrate during further processing steps; and to provide mechanical integrity for the laminate.

The planarization layer is in the range of about 10 to 20 μm thick. It is believed that the web of flexible amorphous polymeric substrate with the embossed receptor recesses combined with the planarization layer is a new subassembly, capable of being continuously formed in an efficient manner.

While prior art planarization techniques have required extended baking of the subassembly at elevated temperatures, the applicants herein have developed an alternative embodiment in which the planarization layer can be provided as a resin that is UV curable or otherwise photopolymerizable. This would allow the planarization layer to be applied and cured at room temperature, thus eliminating the prolonged higher temperature (Tₚ) baking step. A lower Tₚ could greatly expand the acceptable choices for Theological amorphous polymeric materials for use in the substrate 200. Such a photopolymerizable planarization layer could facilitate a roll-to roll coating process at room temperature, while providing the advantages of good optical properties, good chemical resistance, good hardness, and lower cost. Potential materials for this purpose are Vacrel (DuPont) and Carapace EP 100 (Electra).

Such a resin planarization layer could also provide other advantages. Instead of forming the via holes by lithography, a spot laser such as IR or excimer or other laser could be used. This would eliminate the photomask and the potentially damaging wet chemical etching process used in lithography. Thus the requirements for chemical resistance could be less stringent. This would also relax the dimensional accuracy and stability requirements. Each of these could broaden the selection parameters for the underlying substrate material. It would also improve manufacturing yield for large, high-resolution flexible plastic displays using the FSA process.

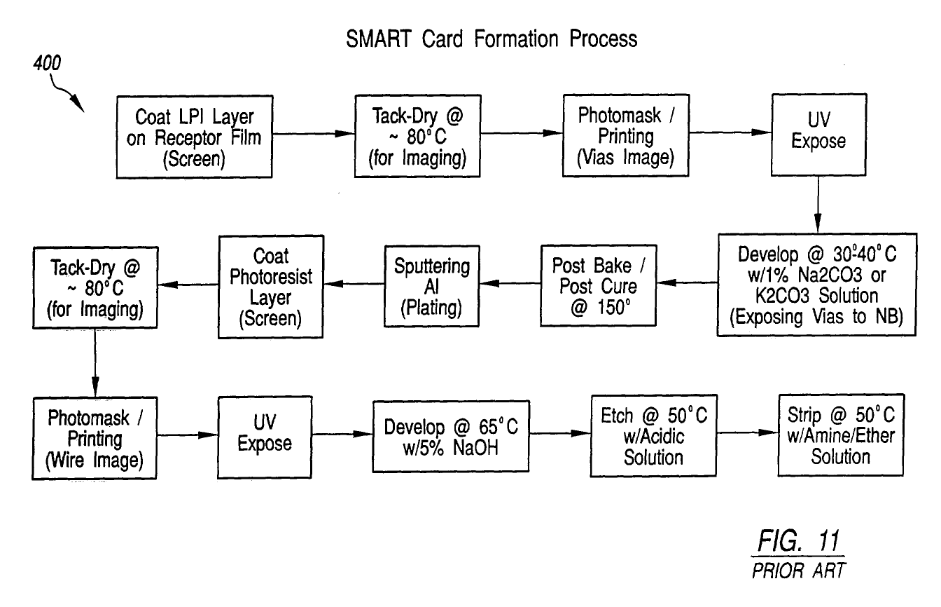

The substrate 200 of the present invention also should have unique performance capabilities when used in the manufacture of smart cards, including the potential for improved registration and enhanced rigidity. The various major process steps for smart card manufacture and the various chemicals and temperature exposures are illustrated in FIG. 11. In this instance, it will be understood that the process in fact starts with formation of the receptor recesses 210 in an underlying substrate 200, followed by the FSA process 320 of applying the microelectronic elements 100 to the substrate. Following the formation process and FSA, the temperatures and materials used for manufacturing the smart card are generically described in FIG. 11.

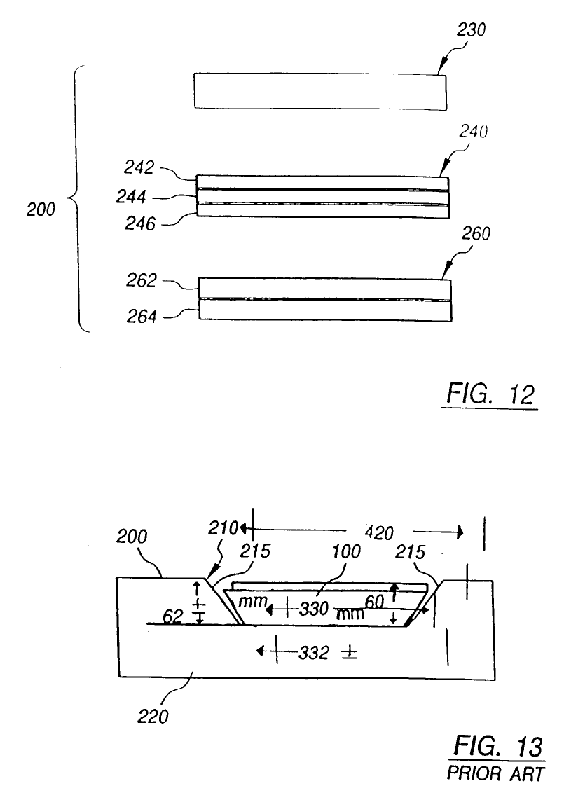

FIG. 12 illustrates at least three types of potential substrates 200. Substrate material 230 is a monolayer comprising one of the thermoplastic materials disclosed herein. Substrate material 260 comprises two layers, a first polymer layer 262 of about 60 μm, and a compatible second polymer layer 264 having a higher Tₚ capability and being about 115 μm thick. Illustrated as substrate 240 is a trilayer having a first polymer 242 about 62.5 μm thick, a second layer 244 of a high temperature compatible polymer or some other fiber form material about 50 μm thick, and a third layer 246 consisting of the same material as the first polymer 242.

The multiple layer constructions may incorporate the same polymer or different polymer constructions with high T_{g} and lower T_{g} layers. It is contemplated that multiple layers can be either laminated or coextruded and may even have a polymer layer joined to a microfiber reinforced layer (the fiber diameter being sufficiently fine, such as two to three mil fiber). It may even be possible to laminate a third nonpolymeric material in the middle, but further processing aspects and differences in coefficients of expansion between polymeric and other inorganic materials could make this difficult to accomplish.

The multiple layer substrates may be provided in several different ways. In the first instance, the layers can be joined in a composite laminate by feeding two or more layers at the input side of the embossing equipment, or in a manner as disclosed in copending application Ser. No. 09/489,789, filed Jan. 24, 2000, entitled Multilayer Lamination with Microstructures, commonly assigned, the subject matter of which is incorporated herein by reference. Alternatively, the layers can be coextruded and bonded to one another. Finally, two layers may be laser fused where they would absorb the heat energy and heat up only at the interfaces where they would be bonded.

Potential materials candidates for these multilayer constructions are set forth in the table herebelow:

TABLE I

| Polymer | PMMA | BPA- | Polyarylate | BPA-PC | Polyarylate |
|---|---|---|---|---|---|
| 1 | | PC | | | |
| Polymer | BPA- | PET | Phenoxy | Polyarylate | PET |
| 2 | PC | | | | |

| Symbol | Polymer Chemical Name | T_{g} deg. C. |
|---|---|---|
| PMMA | Polymethyl methacrylate | 100 |
| BPA-PC | Bisphenol-A Polycarbonate | 150 |
| PET | Polyethylene terephalate | 70 |
| Polyarylate | Polyarylate | 210 |
| Phenoxy | Phenoxy PKHH | 95 |

In the exemplary cross-section of an LCD device illustrated in FIG. 10, the lower layer 200 will consist of the polymer based flexible substrate 220, with the NanoBlock or microelectronic elements 100 positioned in the recesses 210. Overlying the general surface is the dielectric planarization layer 235, above which may be aluminum wiring 365 laid down by a photoresist. Finally, there may be a top layer 385 of an electro-optic material such as a PDLC, OLED, or the like.

As illustrated in FIG. 9, the conductor 365 is deposited on the planarized layer 235. The conductor may be aluminum, copper, silver, a conductive polymer, metal particles, conductive organic compounds, conductive oxides, or other appropriate conductive material. The conductor may be deposited by sputtering or evaporation coating, and the pattern itself may be interconnected using appropriate photolithography techniques known to those skilled in the art. In this instance, the pattern may be interconnecting devices creating a pixel pattern of electrodes.

Numerous substrate materials were tested by embossing them using an apparatus generally of the type described with reference to FIG. 14 herein. A tool for replicating the needed array for the present shaped recesses such as 210 also was used satisfactorily.

It has been found, using the Theological window conceived herein, that polymers selected from the group consisting of polysulfone, polyarylate, cyclo-olefinic copolymer, high T_{g} polycarbonate, and polyether imide can be successfully embossed and meet most of the general specifications for dimensional stability and chemical resistance.

At least five different materials were tested experimentally as identified herebelow and found to satisfy the rheological window as specified herein, viz wherein the substrate employed in the method comprises a first layer of an amorphous polymeric material, the material having an embossing temperature Tₑ at which Tₑ the elastic modulus of the substrate is less than about 1×10⁸ dynes/cm² and in some preferred cases less than about 1×10⁶ dynes/cm, and the viscoelastic index of the substrate is greater than about 0.3, the substrate being capable of subsequent processing at a processing temperature Tₚ, such that after about one hour at Tₚ the substrate has a dimensional stability of <0.01% change in dimension, an elastic modulus of greater than about 10¹⁰ dynes/cm², and a viscoelastic index of less than about 0.1. These materials also provide the necessary chemical resistance and they can satisfactorily be embossed and predictably satisfy the other specifications noted hereinabove.

TABLE II

| | | | Copolymer of |
|---|---|---|---|
| Polymer Type | Polysulfone | Polyarylate (PA) | Norbornenes |
| Commercial Name | Udel-P-1700 | Ardel-D-100 RA | Zeonor 1600 |
| Supplier | Amoco | Amoco | Nippon Zeonor |
| Processing Temp T_{P} | 260° C. | 260° C. | 260° C. |
| Tg° C. | 190 | 210 | 163 |
| 24 Hour Hhd 20 Absorption, % | 0.3 | 0.26 | <0.01 |
| Room Temperature Modulus | 2.00E+10 | 1.80E+10 | 2.00E+10 |
| (E′, dynes/cm²) | | | |
| E′ (dynes/cm²) at 260° C. | 1 .20E+05 | 3.00E+05 | 1.50E+05 |

| | |
|---|---|
| High T_{g} Polycarbonate | Polyetherimide (PI) |

| | |
|---|---|
| Bayfol LP-202 | Tempalux (Ultem-1000) |
| Bayer | GE-Plastics |
| 260° C. | 260° C. |
| 203 | 215 |
| 0.25 | 0.25 |
| 1.70E+10 | 2.00E+10 |
| 1.00E+07 | 6.00E+07 |

In a preferred embodiment, the rheological window requires Tₚ (post embossing, processing temperature) ≦260° C. and T_{g}>150° C., where Tₚ is defined as the highest post embossing processing temperature to which the substrate will be subjected.

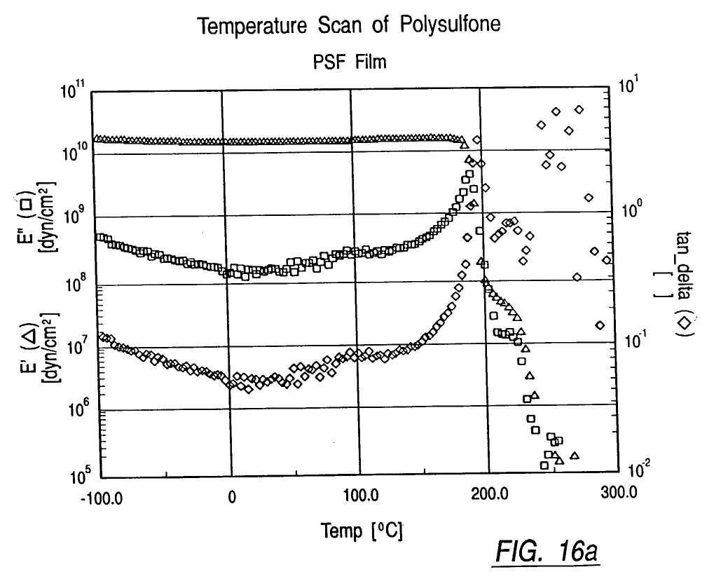

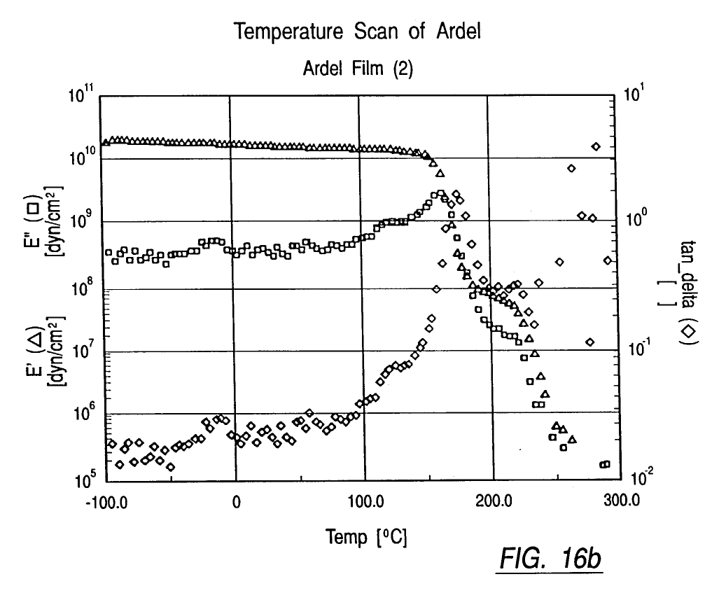

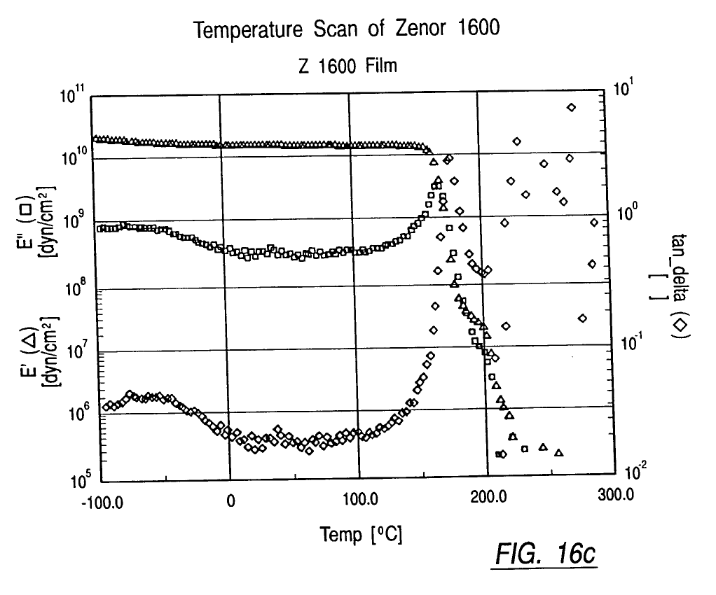

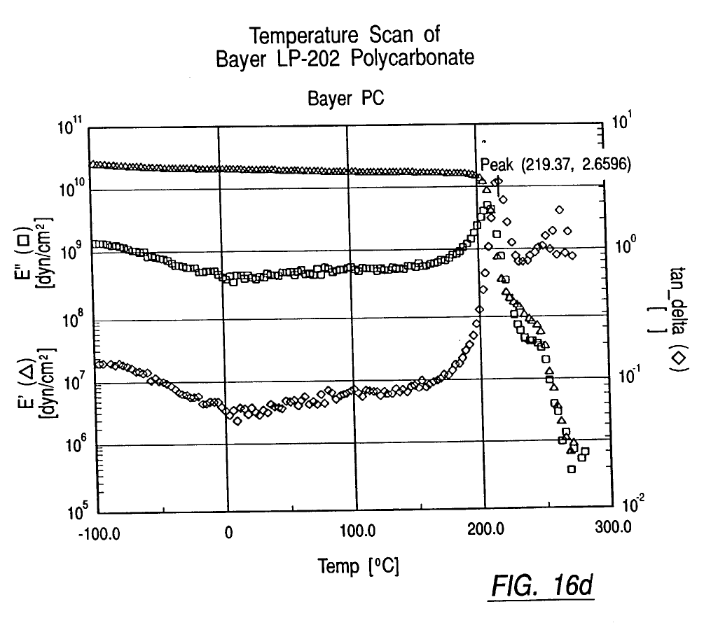

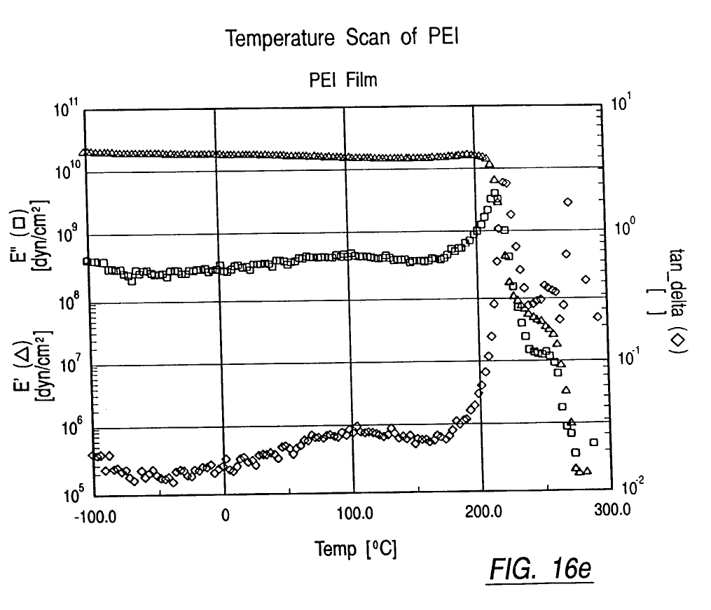

The relationship between E′, E″, and tan delta vs. temperature of these various tested materials are disclosed in the graphs of FIG. 16A through 16E. FIGS. 16A through 16E show the temperature dependence of E′ (Dynamic Tensile Storage modulus), E″ (Dynamic Tensile Loss modulus) and tan delta (viscoelastic index) of Polysulfone, Ardel (Polyarylate), Zeonor 1600, LP-202 Polycarbonate and PEI (Polyetherimide). It can be observed that at 150° C., which is the processing temperature Tₚ for the planarizing layer, all these polymers are in the glassy state, with E′ values >10¹⁰ dynes/cm². The actual values are listed in Table II. Glassy state at the processing temperature ensures that these polymers should be dimensionally stable. As the temperature is raised, the E′ values of all the five polymers show the common characteristic of precipitously dropping several decades at a temperature corresponding to their T_{g}. Such T_{g} can be easily characterized by the temperature where the tan delta value shows a maximum. The T_{g} of these polymers are as shown in Table II.

As the temperature is raised further, the E′ curve shows a short plateau corresponding to the rubbery state, after which E′ shows another precipitous drop corresponding to the flow region. In order to be processable at 260° C., the E′ value has to be <10⁸ dynes/cm² and preferably 10⁶ dynes/cm² and tan delta >0.3 at the processing temperature. Rheologically speaking, for the polymer to go from the glassy state at 150° C. to a flow state at or below 260° C., the polymer has to exhibit a very short plateau region range of temperature, so that after the glass transition, it almost immediately goes to the flow region.

The rheological testing measurements were determined using the ASTM D-5026-93 Standard Test Method for Measuring the Dynamic Mechanical Properties of Plastics in Tension.

In conducting these experiments, the depth of the recesses 210 was measured using a Wyko Surface Morphology Microscope (SMM). Measurements were taken in several locations for each sample tested, and the distance between two embossed recesses and the dimension of the embossment also were measured using an optical microscope with an ImagePro software program. Materials were tested both before and after aging at 150° C. for an hour. After aging, no significant change was found, except a 6% change for PMMA, which is unacceptable. Other combinations noted in Table I proved fairly consistent but are subject to further refinement. Optical analyses were carried out using an Olympus O BX-60 microscope.

A preferred machine 500 for producing the embossed substrate 200 is shown in elevation in FIG. 14, suitably mounted on a floor 502. The machine 500 includes a frame 504, centrally mounted on which is an embossing means 505.

A supply reel 508 of unembossed thermoplastic web 510 is mounted on the right-hand side of the frame 504; so is a supply reel 512 of flexible plastic carrier film 515. The web 510 may be 0.005 inches (125 μm) thick and the film 515 may be about 0.002 inches (50 μm) thick. The flat web 510 and the film 515 are fed from reels 508 and 512, respectively, to the embossing means 505, and over guide rollers 520, in the direction of the arrows. For present purposes, the roll of film may be about 7 inches (19.05 cm) wide.

The embossing means 505 includes an embossing tool in the form of an endless metal belt 530 which may be about 0.020 inches in (0.5 mm) thickness, 36 inches (91.44 cm) in “circumference” and 10 inches (25.4 cm) wide. The width and circumference of the belt 530 will depend in part upon the width of the material to be embossed, the desired embossing speed, and the thickness of the belt 530. The belt 530 is mounted on and carried by a heating roller 540 and a shoe 550 having multiple rollers 551 with parallel axes. The roller 540 is driven by a chain (not shown) to advance the belt 530 at a predetermined linear speed in the direction of the arrow. The belt's outer surface has a continuous male embossing pattern 560 (FIG. 5) that matches the general size and shape of the particular blocks (100) for which the embossed recesses (210) are designed.

Evenly spaced sequentially around the belt, for about 180° around the heating roller 540, are a plurality, at least three, and as shown five, pressure rollers 570 of a resilient material, preferably silicone rubber, with a durometer hardness ranging from Shore A 20 to 90, but preferably, from Shore A 60 to 90. The rollers 570 are shown in dashed lines in two positions, engaged or retracted. The roller position and applied pressure may depend on the film material and its T_{g}.

In the machine 500 as constructed, the diameter of the heating roller 540 is about 35 inches (88.9 cm) and width is about 14 inches (35.6 cm). The diameter of each pressure roller 570 is about 5 inches (12.7 cm). The shoe 550 has 40 idler rollers 551 of stainless steel, each about ¾ inch (19 mm) in diameter. The shoe 570 and rollers 571 are arranged so that the belt 530 is raised off of the heating roller 540 as it rotates, and then returns to the roller. Removing the belt enables it to cool quickly, and cooling is facilitated by a cooling knife or blade 555 positioned just prior to the shoe 550. The shoe also may be hollow and a chilled fluid may flow through it.

Depending on the material selected, it may be desirable to maintain additional pressure about the tool and substrate during cooling, in which case the laminate will be directed to leave the shoe at a later point. As will be desired, the frame 504 permits a variety of positions for the various rolls.

The heating roller 540 may have axial inlet and outlet passages (not shown) joined by an internal spiral tube (not shown) for the circulation therethrough of hot oil (in the case of the heating roller 540) or other material (in the case of the shoe 550) supplied through appropriate lines (not shown). The embossing equipment 500 is an improvement over that disclosed in aforesaid U.S. Pat. Nos. 4,486,363 and 4,601,861. The equipment may employ the improvements disclosed and claimed in U.S. application Ser. No. 09/231,197, entitled “Method and Apparatus for Embossing a Precision Pattern of Micro-Prismatic Elements in a Resinous Sheet or Laminate,” commonly assigned, the disclosure of which is incorporated herein by reference, filed Jan. 14, 1999, and issued Mar. 13, 2001 as U.S. Pat. No. 6,200,399 B1.

The web 510 and the film 515, as stated, are fed to the embossing means 540, where they are superimposed to form a laminate 580 which is introduced between the belt 530 and the leading pressure roller 570, with the web 510 positioned between the film 515 and the belt 530. From there, the laminate 580 is moved with the belt 530 to pass under the remaining pressure rollers 570 and around the heating roller 540 and from there along the belt 530 around a portion of the shoe 550. Thus, one face of the web 510 directly confronts and engages the embossing pattern 560 and one face of the film 515 directly confronts and engages the pressure rollers 570.

The film 515 provides several functions during this operation. First, it serves to keep the web 510 pressed against the belt 530 while they travel around the heating and cooling rollers 540 and shoe 550 and traverse the distance between them. This assures conformity of the web 510 with the precision pattern 500 of the tool as the web (now embossed substrate) drops below the glass transition temperature of the material. Second, the film 515 provides on the lower unembossed surface of the substrate, a flat and highly finished surface suitable for other processing, if desired. Finally, the film 515 acts as a carrier for the web 510 in its weak “molten” state and prevents the web from adhering to the pressure rollers 570 as the web is heated above the glass transition temperature. A number of possible candidates exist for the carrier film, including polyester Mylar; PEN; poly ether ether-ketone; thermoplastic polyimide (Imidex); polyimide (Kapton); and others suggested in the aforesaid copending application Ser. No. 09/489,789.

The embossing means 505 includes a stripper roller 585, around which the laminate 580 is passed, to remove the same from the belt 530 shortly after the belt 530 itself leaves the heating roller 540 on its return path to the shoe 550.

The laminate 580 is then fed from the stripper roller 585 where it is wound onto a storage winder 590 mounted frame 504 at the lefthand end thereof and near the bottom thereof.

The heating roller 540 is internally heated (as aforesaid) so that as the belt 530 passes thereover through the heating station, the temperature of the embossing pattern 560 at that portion of the tool is raised sufficiently to heat the web 510 to a temperature above its glass transition temperature, and to its embossing temperature Tₑ, but not so high as to exceed the melting temperature of the carrier film 515. For the web formed from the different materials forming the substrates herein and the film 515, a suitable embossing temperature Tₑ for the heating roller 540 in the heating station is believed to require a Tₑ at least about 100° C. greater than T_{g} of the polymer. The carrier film 515 may be stripped from the film before or after windup, depending upon other post-embossing processes.

As the belt 530 and substrate pass the cooling knife 555, the temperature of the embossing pattern 560 at that portion of the tool is lowered sufficiently to cool the web 510 to a temperature close to or below its glass transition temperature so that the web becomes sufficiently solid and formed prior to the time laminate 580 is stripped from the tool 530.

It has been found that the laminate 580 can be processed through the embossing means 505 at the rate of about 20 inches (0.5 meter) per minute, with satisfactory results in terms of the accuracy, dimensional stability, and other pertinent properties of the finished substrate. For purposes of the present invention, rolls of embossed film of 200 feet may be provided, and if desired in later processing, butt spliced to like rolls. For smart card processing, ideally the film will be about 6.22″ (158 mm) wide.

It should be noted that reference numeral 510 may refer indiscriminately herein to the embossed substrate 200 or web 510 in its initial form, to its in-process form, or to its final embossed form, as appropriate. Also, as will be described hereinafter, the web itself may comprise several layers of material fed into the embossing equipment.

The term “glass transition temperature” is a well known term of art and is applied to thermoplastic materials as well as glass. The term “glass transition temperature T_{g}” is an important transition temperature applied generally to polymers. It is the temperature at which the polymer or material changes from the glassy state to the rubbery state. In general, the temperature has to be further increased in excess of T_{g} for the polymer to go from the rubbery to the flow state. For example, for Polysulfone, the T_{g} begins at about 190° C., changing into the rubbery state at about 210° C., and begins to flow at 230° C. (Tₑ≧230° C.). For the various extendable types of materials identified as suitable for the substrate 200 herein, the glass transition temperatures T_{g} range from about 325° F. to 410° F. (163° C. to 215° C.).

It will be further understood that the temperatures of the heating roller and cooling shoe may need to be adjusted within certain ranges depending upon the web material selected. Certain materials have a higher T_{g}, and others may require cooling at a higher temperature than normal and for a longer time period. Preheating or additional heating at the entrance of the nips may be accomplished by a laser, by a flameless burner, by an infrared lamp, or another device, and by adjusting the temperature of the heating roller to run at a higher preselected temperature. Similar adjustments may be made at the cooling level.

A preferred material for the embossing tool 530 disclosed herein is nickel. The very thin tool (about 0.010 inches (0.254 mm) to about 0.030 inches (0.768 mm)) permits the rapid heating and cooling of the tool 530 and the web 510 through the required temperature gradients while pressure is applied by the pressure rolls and the carrier film. The result is the continuous production of a precision pattern that maintains flatness and angular accuracy while permitting the formation of sharp corners with minimal distortion of other surfaces, whereby the finished substrate provides an array of recesses 210 formed with high accuracy.

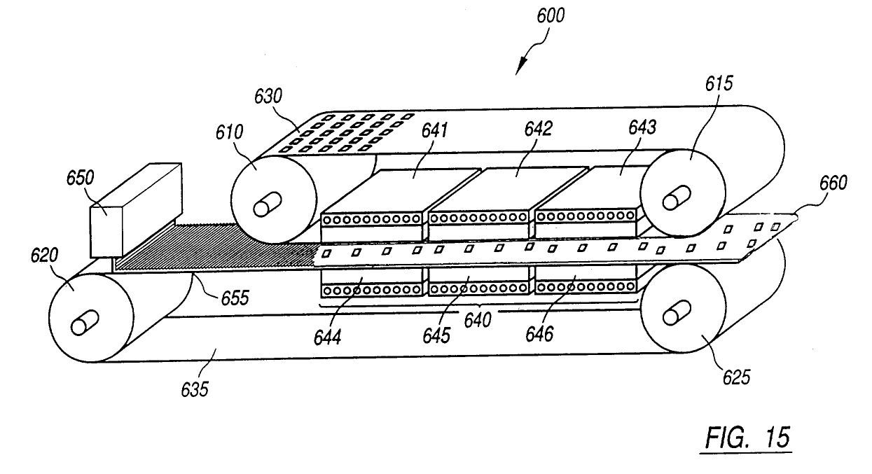

Another form of embossing equipment is shown in FIG. 15. Continuous press machines are known, but it is believed that they have not been used for this purpose before, being used primarily for the formation of thicker laminates for the furniture industry or as plates for fuel cells, as disclosed in co-pending application Ser. No. 09/596,240, filed Jun. 16, 2000, entitled “A Process for Precise Embossing”, and commonly assigned, incorporated herein by reference. Such continuous presses include double band presses which have continuous flat beds with two endless bands or belts, usually steel, running above and below the product and around pairs of upper and lower drums or rollers. These form a pressure or reaction zone between the two belts and advantageously apply pressure to a product when it is flat rather than when it is in a curved form. The double band press also allows pressure and temperature to vary over a wide range. Dwell time or time under pressure is easily controlled by varying the production speed or rate, and capacity may be changed by varying the speed, length, and/or width of the press.

In use, the product is “grabbed” by the two belts and drawn into the press at a constant speed. At the same time, the product, when in a relatively long flat plane, is exposed to pressure in a direction normal to the product. Of course, friction is substantial on the product, but this may be overcome by one of three systems. One system is the gliding press, where pressure-heating plates are covered with low-friction material such as polytetrafluoroethylene and lubricating oil. Another is the roller bed press, where rollers are placed between the stationary and moving parts of the press. The rollers are either mounted in a fixed position on the pressure plates or incorporated in chains or roller “carpets” moving inside the belts in the same direction but at half speed. The roller press is sometimes associated with the term “isochoric.” This is because the press provides pressure by maintaining a constant distance between the two belts where the product is located. Typical isochoric presses operate to more than 700 psi.

A third system is the fluid or air cushion press, which uses a fluid cushion of oil or air to reduce friction. The fluid cushion press is sometimes associated with the term “isobaric” and these presses operate to about 1000 psi. Pressure on the product is maintained directly by the oil or the air. Air advantageously provides a uniform pressure distribution over the entire width and length of the press.

In all double band presses, heat is transferred to thin products from the heated rollers or drums via the steel belts. With thicker products, heat is transferred from heated pressure plates to the belts and then to the product. In gliding presses, heat is also transferred by heating the gliding oil itself In roller bed presses, the rollers come into direct contact with the pressure-heating plates and the steel belts. In air cushion presses, heat flows from the drums to the belts to the product, and, by creating a turbulence in the air cushion itself, heat transfer is accomplished relatively efficiently. Also, heat transfer increases with rising pressure.

Another advantage of the double band press is that the product may be heated first and then cooled, with both events occurring while the product is maintained under pressure. Heating and cooling plates may be separately located one after the other in line. The belts are cooled in the second part of the press and these cooled belts transfer heat energy from the product to the cooling system fairly efficiently.

Continuous press machines fitting the general description provided hereinabove are sold by Hymmen GmbH of Bielefeld, Germany (U.S. office: Hymmen International, Inc. of Duluth, Ga.) as models ISR and HPL. These are double belt presses and also appear under such trademarks as ISOPRESS and ISOROLL. To applicants' knowledge, such presses heretofore have not been used to emboss precise recesses, especially with polymeric materials of the group designated herein.

The present invention offers numerous advantages and relates to a process for making thermoplastic products having precise embossed recesses, comprising the following steps: providing a continuous press with an upper set of rollers, a lower set of rollers, an upper belt disposed about the upper set of rollers, a lower belt disposed about the lower set of rollers, a heating station, a cooling station, and pressure producing elements; passing an amorphous thermoplastic material through the press; heating the material to about 490° F. (255° C.); applying pressure of at least about 250 psi (17 bars) to the material; cooling the material to near its T_{g} and, if desired, maintaining pressure on the material while the material is cooled.

Referring now to FIG. 15, a continuous press is illustrated. The press 600 includes a pair of upper rollers 610, 615 and a pair of lower rollers 620, 625. The upper roller 610 and the lower roller 620 may be oil heated. Typically the rollers are about 31.5 inches in diameter and extend for about 27.5 inches (70 cm). Around each pair of rollers is a steel (or nickel) belt 630, 635. An upper patterned belt 630 is mounted around the upper rollers 610, 615 and a lower plain belt 635 is mounted around the lower rollers 620, 625. Only a portion of the pattern is illustrated, but it is understood that it will contain an array of male elements, as at 560 (FIG. 5) designed to provide the necessary size and shape of the receptor recesses 210.

These belts may be generally similar to those continuous belts described above in conjunction with the continuous roll embossing process, for machine 500.

Heat and pressure are applied in a portion of the press referred to as the reaction zone 640. Within the reaction zone are means for applying pressure and heat, such as three upper matched pressure sections 641, 642, 643 and three lower matched pressure sections 644, 645, 646. Each section is about 39 inches (100 cm) long and the width depends on the width of roll desired, one example being 27.5 inches (27.5 cm). Heat and pressure may be applied by other means as is well known by those skilled in the art. Also, it is understood that the dimensions set forth are for existing or experimental continuous presses, such as those manufactured by Hymmen; these dimensions may be changed if desired.

The lower belt 635 will be smooth if only one side of a product is to be embossed. It is to be understood that the pressure sections may be heated or cooled. Thus, for example, the first two upstream pressure sections, upper sections 641, 642 and the first two lower sections 644, 645 may be heated whereas the last sections 643 and 646 may be cooled or maintained at a relatively constant but lower temperature than the heated sections.

It is contemplated that thermoplastic materials such as polysulfone, polyarylate, high T_{g} polycarbonate, polyetherimide, and copolymers may be used in the press 600 (or the embossing machine 500). With such material, the pressure range is approximately 180 to 1430 psi and the temperature range is approximately 485° F. to 580° F. (250° C. to 340° C.). Material thicknesses of 75 μm to 250 μm may be embossed to provide the desired receptor recesses.

With the dimensions and reaction zones stated above, the process rate may move at about 21 to 32 feet per minute, roughly ten times the rate of prior art continuous roll machines such as illustrated in FIG. 14.

The present invention thus has provided a predictive technique for determining a flexible substrate material capable of being embossed to define highly precise recesses facilitating an FSA process, and by such selection of appropriate material, provides new combinations of articles and intermediate products.

The invention, in its various aspects and disclosed forms, is well adapted to the attainment of the stated objects and advantages and others. The disclosed details are not to be taken as limitations on the invention, except as those details may be included in the appended claims. The embodiments of the invention in which an exclusive property or privilege is claimed are as follows:

What is claimed is:

1. A substrate having embossed thereon a plurality of shaped recesses of predetermined dimensions, each recess having a flat bottom surface, the length and width of such flat bottom surface each being about 1000 μm or less, said substrate comprising an amorphous thermoplastic material such that said substrate is capable of undergoing a thermal cycle of about one hour at about 150° C. while maintaining about ±10 μm or less dimensional stability of said embossed shaped indentations.

2. The substrate of claim 1, wherein during said thermal cycle said substrate has an elastic modulus greater than about 10¹⁰ dynes/cm².

3. The substrate of claim 1, wherein during said thermal cycle said substrate has a viscoelastic index of less than about 0.1.

4. The substrate of claim 1, wherein said substrate is substantially chemically inert to an aqueous solution of about 5% non-ionic surfactant.

5. The substrate of claim 1, wherein said substrate is substantially chemically inert to a solution containing propylene glycol monomethyl ether acetate.

6. The substrate of claim 1, wherein said substrate is substantially chemically inert to a solution comprising phosphoric acid, acetic acid, and nitric acid.

7. The substrate of claim 1, wherein said substrate is substantially chemically inert to a solution containing monoethanolamine.

8. The substrate of claim 1, wherein said amorphous thermoplastic material is in the form of a flexible web capable of being wound about a core.

9. The substrate of claim 1, wherein during said thermal cycle the spacing of said recesses from specified reference points does not vary by more than about ±20 μm.

10. The substrate of claim 1, wherein each recess is at least about 5 μm deep.

11. The substrate of claim 1, wherein each recess has a substantially rectangular bottom surface and four outwardly sloping side walls.

12. The substrate of claim 1, wherein said amorphous thermoplastic material is selected from the group consisting of polyarylate, polysulfone, polyetherimide, cyclo-olefinic copolymer, and high Tg polycarbonate.

13. The substrate of claim 1, wherein said substrate is a multi-layer structure.

14. An article comprising
(a) a substrate comprising a first amorphous thermoplastic layer having embossed on a first surface thereof a plurality of recesses of predetermined dimensions, each recess having a flat bottom surface, the length and width of said flat bottom surface each being about 1000 μm or less;
(b) a plurality of microstructures respectively disposed within said recesses, said microstructures having dimensions complementary to the dimensions of said recesses; and
(c) a planarization layer disposed over said microstructures and said first surface of said amorphous thermoplastic substrate.

15. The article of claim 14, wherein said substrate further comprises a second amorphous thermoplastic layer disposed opposite said first surface of said amorphous thermoplastic layer in laminar configuration therewith, said second amorphous thermoplastic layer having a dimensional stability of <0.01% change in dimension, an elastic modulus of greater than about 10¹⁰ dynes/cm², and a viscoelastic index of less than about 0. 1, all at a temperature of about 150° C. for about 1 hour.

16. The article of claim 15, wherein said second amorphous thermoplastic material is selected from the group consisting of high T_{g} polycarbonate, poly(ethylene terephthalate),and polyarylate.

17. The article of claim 14, wherein said substrate comprises two layers in laminar configuration, said first layer of said substrate having said recesses embossed thereon and said second layer having a dimensional stability of <0.01% change in dimension, an elastic modulus of greater than about 10¹⁰ dynes/cm², and a viscoelastic index of less than about 0. 1, all at a temperature of about 150° C. for about 1 hour.

18. The article of claim 14, wherein said planarization layer comprises a dielectric material.

19. The article of claim 14, wherein said planarization layer comprises a polymerizable resin.

20. The article of claim 19, wherein said resin is polymerizable via actinic radiation.

21. The article of claim 19, wherein said resin is polymerizable via UV curing.

22. A method for forming an amorphous thermoplastic product having precise embossed surfaces requiring sharp angles and flatnesses, comprising the steps of:
providing a continuous press having a pair of opposed belts, at least one of said belts having a predetermined pattern;
passing a web of amorphous thermoplastic material between said opposed belts;
heating said material to at least above its glass transition temperature to the embossing temperature of said amorphous thermoplastic material;
applying pressure to said amorphous thermoplastic material through said belts sufficient to emboss said predetermined pattern on a surface thereof; said pattern including an array of sparced receptor recesses having a depth between 5 and 100 μm, an upwardly tapered wall at an angle of 20°-70°, a flat bottom parallel to the top surface of said material, said bottom wall having a major dimension of 1000 μm or less; and
cooling said amorphous thermoplastic material to below its glass transition temperature.

23. A method of assembling a microstructure on a substrate, said substrate comprising a top surface with at least one recessed region thereon, said method comprising the steps of: 1) providing a slurry comprising a plurality of shaped blocks and a fluid; 2) transferring said slurry over said substrate at a rate at which at least one of said shaped blocks will self align and be disposed into a recessed region; and 3) subjecting said substrate with said shaped blocks disposed therein to elevated temperatures for subsequent processing, and
wherein the substrate employed in the method comprises a first layer of an amorphous polymeric material, said material having a glass transition temperature T_{g} and an embossing temperature Tₑ, at which Tₑ the elastic modulus of the substrate is less than about 1×10⁸ dynes/cm² and the viscoelastic index of the substrate is greater than about 0.3, and said substrate being capable of subsequent processing at a processing temperature Tₚ, such that after about one hour at Tₚ the substrate has a dimensional stability of <0.01% change in dimension, an elastic modulus of greater than about 10¹⁰ dynes/cm², and a viscoelastic index of less than about 0.1.

24. The method of claim 23, wherein at Tₑ the elastic modulus of said substrate is less than about 1×10⁶ dynes/cm².

25. The method of claim 24, wherein said subsequent processing comprises the application of a planarization layer comprising a dielectric material overlying said microstructure blocks, said recesses and said substrate.

26. The method of claim 24, wherein said subsequent processing comprises the application of a planarization layer comprising a polymerizable resin.

27. The method of claim 26, wherein said resin is polymerizable via actinic radiation.

28. The method of claim 26, wherein said resin is polymerizable via UV curing.

29. The method of claim 26, further including laser forming of vias through the planarization layer to permit predetermined conductive access to said microstructure blocks in the covered recesses.

30. An article comprising
a flexible substrate having at least one layer, said layer consisting of an amorphous thermoplastic material having a plurality of micro recesses of predetermined dimensions embossed therein, wherein each recess has a flat bottom surface, the length and width of said flat bottom surface each being about 1000 μm or less; an upwardly tapered wall at an angle of between 50°-70° to the normal of the substrate, a height of between about 5 μm to 100 μm, and an upper opening between about 10 μm to 1000 μm in major dimension.

31. The article of claim 30, wherein the spacing of recesses relative to predetermined references points does not vary by ±20 μm or less.

32. The article of claim 30, wherein at least one recess is in the form of a truncated four sided pyramid, having a depth of about 69 μm, angled walls of about 57°, and a base of about 280 μm by 280 μm and a top of about 380 μm by 380 μm.

33. The article of claim 30, wherein the substrate has a thickness of about 180 μm.

34. The article of claim 30, wherein the substrate is formed of a polymeric material selected from a group in which the glass transition temperature T_{g} is between 163° C. and 215° C., and wherein at embossing temperature Tₑ the material has an elastic modulus less than about 1×10⁸ dynes/cm² and a viscoelastic index greater than about 0.3 if processed up to 150° C. and has dimensional stability of <0.01% change and an elastic modulus of greater than about 10¹⁰ dynes/cm², and a viscoelastic index of less than about 0.1.

35. The article of claim 34, wherein at a temperature Tₑ, the elastic modulus is less than about 1×10⁶ dynes/cm^{2.}

36. The article of claim 30, and further including at lease of microstructure block disposed in each respective recess, and wherein a planarization layer overlies the blocks and is adhered to the surface of the substrate having the recesses embossed therein.

37. The article of claim 36, wherein the planarization layer is formed of a polymerizable resin.
